(19) United States
(12) Patent Application Publication
(10) Pub. No.: US 2025/0316452 A1
(43) Pub. Date: Oct. 9, 2025

(54) DELIVERY OF PULSED VOLTAGE WAVEFORMS TO IMPROVE STEP COVERAGE AND DAMAGE CONTROL

(71) Applicant: Applied Materials, Inc., Santa Clara, CA (US)

(72) Inventors: Bencherki MEBARKI, Santa Clara, CA (US); Joung Joo LEE, San Jose, CA (US)

(21) Appl. No.: 18/626,738

(22) Filed: Apr. 4, 2024

(51) Int. Cl. H01J 37/32; H01L 21/02

(52) U.S. Cl. CPC H01J 37/32146; H01J 37/32128; H01L 21/02274; H01J 2237/3321

(57) ABSTRACT

Embodiments of the disclosure include a method for fabricating a semiconductor device, comprising: forming, within a physical vapor deposition (PVD) chamber, a first layer by use of a PVD process on a surface of substrate that comprises a plurality of features formed therein, wherein forming the first layer comprises biasing a target within the process chamber; and etching, within the PVD chamber, at least a portion of the first layer. The etching process comprises: applying a substrate bias to an electrode disposed within a substrate support near a substrate receiving surface, wherein applying the substrate bias comprises delivering a pulsed-voltage (PV) waveform to the electrode; and exposing the substrate to a plasma generated within the PVD chamber.

### BACKGROUND

### Field

Embodiments of the present disclosure generally relate to a method of substrate processing. More specifically, embodiments of the present disclosure relate to a method of using pulsed voltage waveforms to improve step coverage and damage control.

### Description of the Related Art

The field of semiconductor device fabrication is constantly evolving, with new materials, processes, and equipment being developed to meet the growing demand for smaller, faster, and more complex devices. One challenge in device fabrication is the need to deposit thin films of various materials with high quality, uniformity, and precision. Another challenge is reliably producing high aspect ratio features.

Physical vapor deposition (PVD) is a common technique used for depositing thin films of various metals and metal alloys. However, PVD deposition can cause damage to the underlying layers of the substrate, particularly when high-energy ions are used to enhance the deposition rate or when the substrate features are small and have high aspect ratios. This damage can lead to poor step coverage and other defects, which can compromise the performance and reliability of the device. Further, when depositing thin films over high aspect ratio features, the thin film material may form a step, or overhang, or other undesirable geometry, over a portion, or the entirety, of the high aspect ratio. Including the suboptimal film profile caused by the overhang, the overhang can also block or reduce blocking deposition to lower portions of the high aspect ratio feature. Accordingly, there is need in the art for improvements to step coverage and damage control.

### SUMMARY

Embodiments of the present disclosure generally relate to a method of substrate processing. More specifically, embodiments of the present disclosure relate to a method of using pulsed voltage waveforms to improve step coverage and damage control during a physical vapor deposition (PVD) process.

Embodiments of the disclosure include a method for fabricating a semiconductor device, comprising: forming, within a physical vapor deposition chamber, a first layer by use of a physical vapor deposition process on a surface of substrate that comprises a plurality of features formed therein, wherein forming the first layer comprises biasing a target within the process chamber; and etching, within the physical vapor deposition chamber, at least a portion of the first layer. The etching process comprises: applying a substrate bias to an electrode disposed within a substrate support near a substrate receiving surface, wherein applying the substrate bias comprises delivering a pulsed-voltage (PV) waveform to the electrode; and exposing the substrate to a plasma generated within the physical vapor deposition chamber.

Embodiments of the disclosure include a method for fabricating a semiconductor device, comprising: forming, within a first physical vapor deposition (PVD) chamber, a first layer on a surface of substrate that comprises a plurality of features formed therein, wherein forming the first layer comprises biasing a target within the first PVD chamber; transferring the substrate from the first PVD chamber to a second PVD chamber; and etching, within the second PVD chamber, at least a portion of the first layer. The etching process comprises: applying a substrate bias to an electrode disposed within a substrate support near a substrate receiving surface, wherein applying the substrate bias comprises delivering a PV waveform to the electrode; and exposing the substrate to a plasma generated within the second PVD chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system, according to one or more embodiments described herein.

FIG. 2 is a cross-sectional view of a chamber according to one or more embodiments described herein.

FIG. 3 illustrates a process flow diagram of a method according to one or more embodiments described herein.

FIG. 4A illustrates a voltage waveform that is established on a substrate due to a voltage waveform applied to an electrode of a processing chamber according to one or more embodiments described herein.

FIG. 4B is a graph illustrating an IED function (IEDF), according to one or more embodiments described herein.

FIGS. 5A-5D illustrate aspects of various chamber processing modes, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a method of substrate processing. More specifically, embodiments of the present disclosure relate to a method of using pulsed voltage waveforms to improve step coverage and damage control.

Physical vapor deposition (PVD) is a common technique used for depositing thin films of various metals and metal alloys. However, PVD deposition can cause damage to the underlying layers of the substrate, particularly when high-energy ions are used to enhance the deposition rate or when the substrate features are small and have high aspect ratios. This damage can lead to poor step coverage and other defects, which can compromise the performance and reliability of the device. Further, when depositing thin films over high aspect ratio features, the thin film material may form a step, or overhang, or other undesirable geometry, over a portion, or the entirety, of the high aspect ratio. Including the suboptimal film profile caused by the overhang, the overhang can also block or reduce blocking deposition to lower portions of the high aspect ratio feature. Accordingly, there is need in the art for improvements to step coverage and damage control.

### Example Processing System

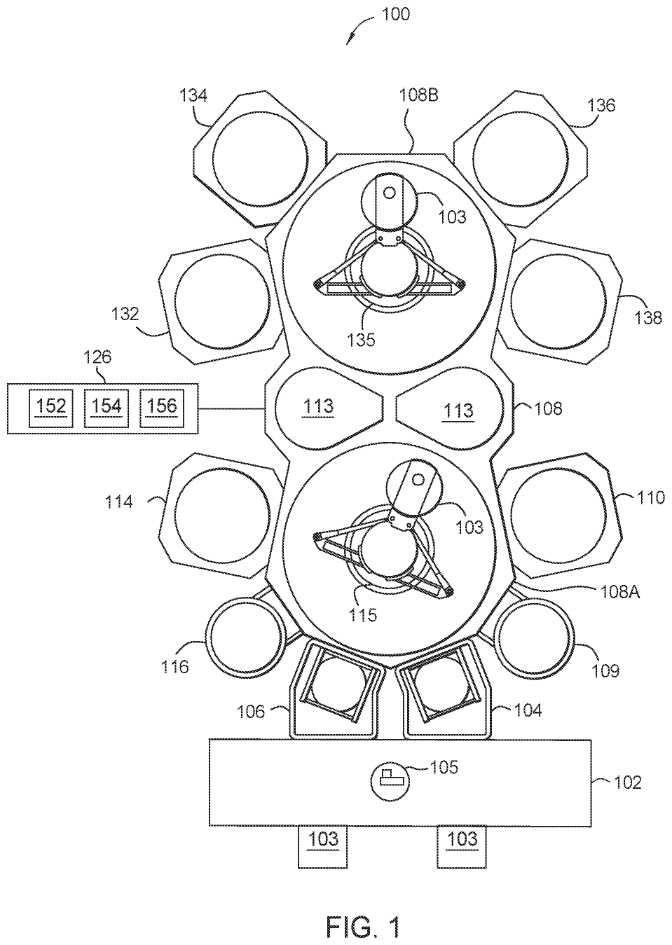

FIG. 1 is a schematic top view of an exemplary processing system 100 (also referred to as a “processing platform”), according to certain embodiments. The processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the FOUPs 103 to at least one of the first load lock chamber 104 or the second load lock chamber 106. Proceeding counterclockwise around the transfer chamber 108 from the buffer portion 108A of the first load lock chamber 104, the processing system 100 includes a first degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are a PVD chamber that configured similar to the processing chamber 200 described below.

The buffer portion 108A and back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the processing system 100 for controlling one or more of the components therein. For example, the system controller 126 may control the operation of the processing chamber 200, which is described further below. In operation, the system controller 126 enables data acquisition and feedback from the respective components to coordinate processing in the processing system 100. The system controller 126 includes a programmable central processing unit (CPU) 152, which is operable with a memory 154 (e.g., non-volatile memory) and support circuits 156. The support circuits 156 (e.g., cache, clock circuits, input/output subsystems, power supplies, etc., and combinations thereof) are conventionally coupled to the CPU 152 and coupled to the various components within the processing system 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the processing system 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Processing Chamber Example

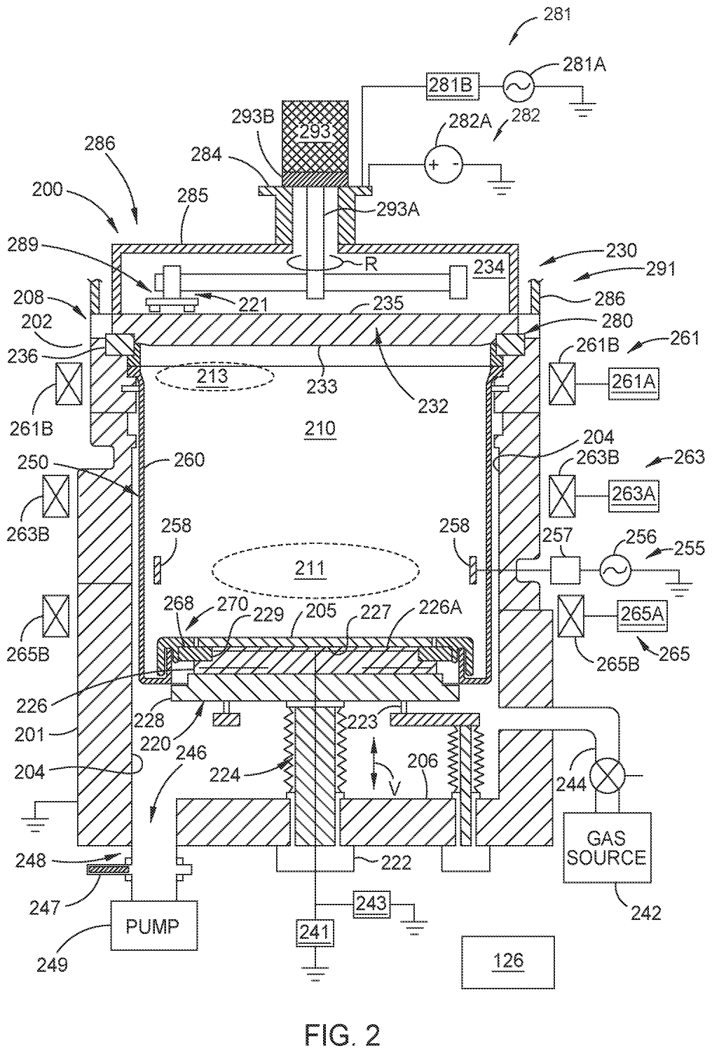

FIG. 2 illustrates an exemplary processing chamber 200 having an upper process assembly 208, a process kit 250 and a pedestal assembly 220, which are all configured to process a substrate 205 disposed in a processing region 210. The process kit 250 includes a one-piece grounded shield 260, a deposition ring 268, a cover ring 270, and an isolator ring assembly 280. In the version shown, the processing chamber 200 comprises a sputtering chamber, also called a PVD chamber, capable of depositing a single or multi-compositional material from a sputtering target 232 on the substrate 205. The processing chamber 200 may also be used to deposit aluminum (Al), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AlOx), lanthanum oxides (LaOx), nickel platinum alloys (NiPt), and titanium (Ti), and or combination thereof. Such processing chambers are available from Applied Materials located in Santa Clara, Calif. It is contemplated that other processing chambers including those from other manufacturers may be adapted to benefit from one or more of the embodiments of the disclosure described herein.

The processing chamber 200 includes a chamber body 201 having sidewalls 204, a bottom wall 206, and an upper process assembly 208 that enclose a processing region 210 or plasma zone. The chamber body 201 is typically fabricated from welded plates of stainless steel or a unitary block of aluminum. In one embodiment, the sidewalls comprise aluminum and the bottom portion of the chamber includes one or more walls that are formed from a stainless steel plate. The sidewalls 204 generally contain a slit valve (not shown) to provide for entry and egress of a substrate 205 from the processing chamber 200. Components in the upper process assembly 208 of the processing chamber 200 in cooperation with the grounded shield 260, pedestal assembly 220 and cover ring 270 confine the plasma formed in the processing region 210 to the region above the substrate 205.

A pedestal assembly 220 is supported from the bottom wall 206 of the processing chamber 200. The pedestal assembly 220 supports a deposition ring 268 along with the substrate 205 during processing. The pedestal assembly 220 is coupled to the bottom wall 206 of the processing chamber 200 by a lift mechanism 222, which is configured to move the pedestal assembly 220 between an upper processing position and lower transfer position. Additionally, in the lower transfer position, lift pins 223 are moved through the pedestal assembly 220 to position the substrate a distance from the pedestal assembly 220 to facilitate the exchange of the substrate with a substrate transfer mechanism disposed exterior to the processing chamber 200, such as a single blade robot (not shown). A bellows 224 is typically disposed between the pedestal assembly 220 and the bottom wall 206 to isolate the processing region 210 from the interior of the pedestal assembly 220 and the exterior of the chamber.

The pedestal assembly 220 generally includes a support 226 sealingly coupled to a platform housing 228. The platform housing 228 is typically fabricated from a metallic material such as stainless steel or aluminum. A cooling plate (not shown) is generally disposed within the platform housing 228 enabling thermal regulation of the support 226.

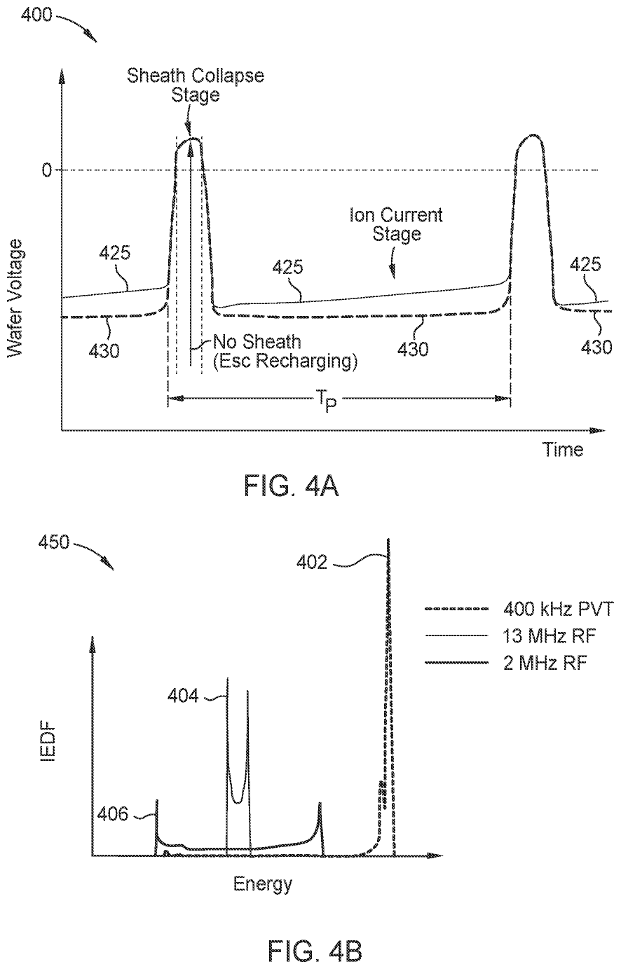

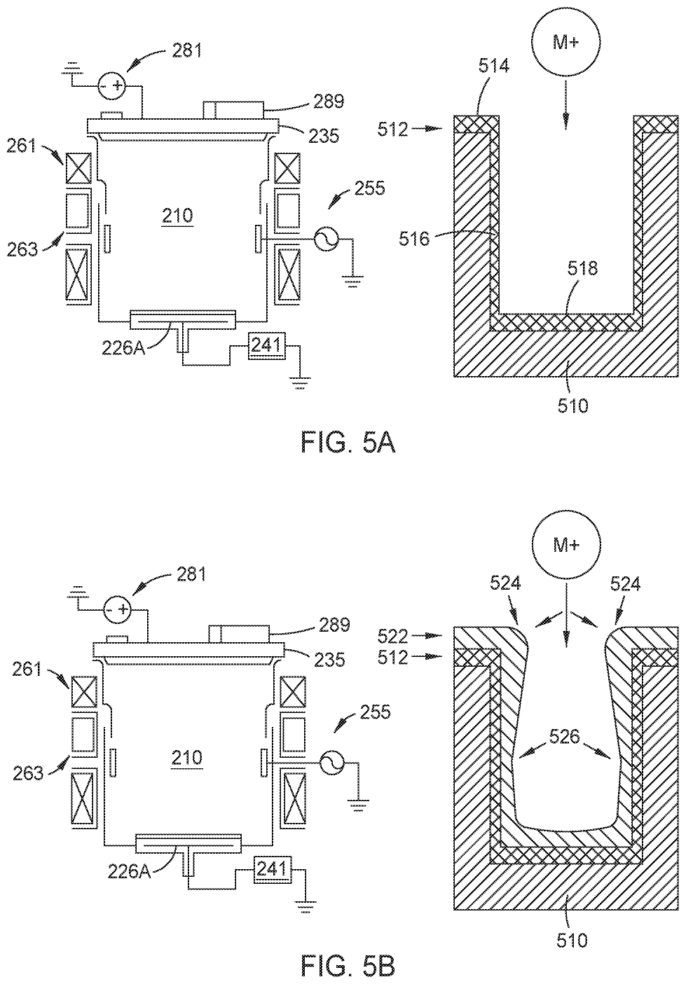

The support 226 may be comprised of aluminum or ceramic. The substrate support 226 has a substrate receiving surface 227 that receives and supports the substrate 205 during processing, the substrate receiving surface 227 being substantially parallel to a sputtering surface 233 of the sputtering target 232. The support 226 also has a peripheral edge 229 that terminates before an overhanging edge 205A of the substrate 205. The support 226 may be an electrostatic chuck, a ceramic body, a heater, or a combination thereof. In one embodiment, the support 226 is an electrostatic chuck that includes a dielectric body having an electrode 226A, embedded therein. The dielectric body is typically fabricated from a high thermal conductivity dielectric material such as pyrolytic boron nitride, aluminum nitride, silicon nitride, alumina or an equivalent material. Other aspects of the pedestal assembly 220 and support 226 are further described below. In one embodiment, the electrode 226A is configured so that when a DC voltage is applied to the electrode 226A, by an electrostatic chuck power supply 243, a substrate 205 disposed on the substrate receiving surface 227 will be electrostatically chucked thereto to improve the heat transfer between the substrate 205 and the support 226. In one embodiment, a bias source 241 is electrically coupled to the electrode 226A, and is configured to generate a pulsed-voltage signal that comprises a pulsed-voltage (PV) waveform (described below in FIGS. 4A and 4B) so that a pulsed voltage signal can be provided to the substrate during processing to affect and control the plasma interaction with the surface of the substrate 205.

A program (or computer instructions) readable by the system controller 126 determines which tasks are performable on a substrate. Preferably, the program is software readable by the system controller 126 that includes code to perform tasks relating to monitoring, execution, and control of the movement and various process recipe tasks and recipe steps being performed in the processing system 100 and processing chamber 200. For example, the system controller 126 can comprise program code that includes a substrate positioning instruction set to operate the pedestal assembly 220; a gas flow control instruction set to operate gas flow control valves to set a flow of sputtering gas to the processing chamber 200; a gas pressure control instruction set to operate a throttle valve or gate valve to maintain a pressure in the processing chamber 200; a temperature control instruction set to control a temperature control system (not shown) in the pedestal assembly 220 or sidewalls 204 to set temperatures of the substrate or sidewalls 204, respectively; and a process monitoring instruction set to monitor the process in the processing chamber 200.

The processing chamber 200 also contains a process kit 250 which comprises various components that can be easily removed from the processing chamber 200, for example, to clean sputtering deposits off the component surfaces, replace, or repair eroded components, or to adapt the processing chamber 200 for other processes. In one embodiment, the process kit 250 comprises an isolator ring assembly 280, a grounded shield 260 and a deposition ring 268 for placement about a peripheral edge 229 of the support 226 that terminates before an overhanging edge of the substrate 205.

The upper process assembly 208 may also comprise an RF source 281, a direct current (DC) source 282, an adaptor 202, a motor 293, and a lid assembly 230. The lid assembly 230 generally comprises a sputtering target 232, a magnetron system 289, and a lid enclosure 291. The upper process assembly 208 is supported by the sidewalls 204 when in a closed position, as shown in FIG. 2. A ceramic target isolator 236 is disposed between the isolator ring assembly 280, the sputtering target 232, and adaptor 202 of the lid assembly 230 to prevent vacuum leakage there between. The adaptor 202 is sealably coupled to the sidewalls 204, and is configured to help with the removal of the upper process assembly 208 and isolator ring assembly 280.

When in the processing position, the sputtering target 232 is disposed adjacent to the adaptor 202, and is exposed to the processing region 210 of the processing chamber 200. The sputtering target 232 contains material that is deposited on the substrate 205 during a PVD, or sputtering, process. The isolator ring assembly 280 is disposed between the sputtering target 232 and the shield 260 and chamber body 201 electrically isolating the sputtering target 232 from the shield 260 and chamber body 201.

During processing, the sputtering target 232 is biased relative to a grounded region of the processing chamber (e.g., chamber body 201 and adaptor 202) by a power source disposed in the RF source 281 and/or the direct current (DC) source 282. It is believed that by delivering RF energy and DC power to the sputtering target 232 during a high pressure PVD process, significant process advantages can be achieved over conventional low pressure DC plasma processing techniques when used in conjunction with sputtering materials such as titanium, copper, nickel, ruthenium, aluminum, tantalum, molybdenum, and tungsten to name just a few. In one embodiment, the RF source 281 comprises an RF power source 281A and an RF match 281B that are configured to efficiently deliver RF energy to the sputtering target 232. In one example, the RF power source 281A is capable of generating RF currents at a frequency of between about 13.56 MHz and about 228 MHz at powers between about 0 and about 5 kWatts. In one example, the DC power supply 282A in the DC source 282 is capable of delivering between about 0 and about 50 kWatts of DC power.

The central portion of the processing chamber 200 includes an inductive coil assembly 255 that is positioned within a central region of the process kit 250, and is configured to form an inductively coupled plasma 211 during processing that is used to ionize atoms ejected from the sputtering target 232 and/or ionize process gases disposed within the processing region 210 during processing. The inductive coil assembly 255 includes an RF power source 256 and an impedance match 257 that are coupled to a RF coil 258, which is disposed within a central portion of the processing region 210 of the processing chamber 200. In some embodiments, the RF coil 258 is positioned at a vertical midpoint in the processing region 210, or at a position between the vertical midpoint and the surface of the substrate 205. The vertical mid-point being defined as the mid-point distance between the substrate receiving surface 227 of the pedestal assembly 220 and the target 232. In some embodiments, the RF coil 258 includes a single turn coil that is formed from a metal, where a first end of the single turn coil is coupled to RF power source 256 through the impedance match 257, and a second end that is coupled to a ground reference. In one configuration, the RF coil 258 is formed from a conductive material that is made of the same material as the sputtering target 232. In some configurations, the RF power source 256 is capable of generating RF currents in RF coil 258 at a frequency of between about 13.56 MHz and about 228 MHz at powers between about 0 and about 5 kWatts.

In some embodiments, the processing chamber 200 also includes one or more auxiliary electromagnet assemblies vertically aligned around the processing chamber, such as a first electromagnet assembly 261, a second electromagnet assembly 263, a third electromagnet assembly 265. In some embodiments, the first, second, and third electromagnet assemblies each include a separate current source so that each assembly can separately generate a magnetic field that is configured to confine and/or control the movement of electrons and ions generated in a plasma formed in the processing region 210 of the processing chamber.

In some embodiments, the first electromagnet assembly 261 comprises a first current source 261A configured to bias a first magnetic coil assembly 261B. The first magnetic coil assembly 261B is positioned near the sputtering target 232, configured to modulate the magnetron controlled plasma 213. The second electromagnet assembly 263 comprises a second current source 263A configured to bias a second magnetic coil assembly 264B. The second magnetic coil assembly 264B is positioned next to the inductive coil assembly 255, configured to modulate the inductively coupled plasma 211. The third electromagnet assembly 265 comprises a third current source 265A configured to bias a third magnetic coil assembly 265B. The third magnetic coil assembly 265B is positioned near the support 226, configured to modulate the plasma near the surface of the substrate 205. In some configurations, the first, second, and third current sources 261A, 263A, and 265A are capable of generating a DC or RF current or voltage at a power between about 0 and about 5 kWatts.

In operation, the one or more electromagnet assemblies 261, 263, and 265 are vertically distributed and positioned outside the process kit 250 to generate magnetic field within the processing region 210 to help alter and/or shape the radial distribution of the plasma formed with the processing region 210 during processing. In some embodiments, the one or more electromagnet assemblies comprise a single electromagnet, a pair of electromagnets, or a quadruple electromagnet array. The quadruple electromagnet array includes four solenoidal coils wrapped generally circularly symmetrically about the central axis 294 of the processing chamber 200. In one configuration, the four electromagnets are configured as top inner magnet (TIM), top outer magnet (TOM), bottom inner magnet (BIM), and bottom outer magnet (BOM) (not shown). The magnetic field generated by the quadruple electromagnet array is modulated by controlling the direction and magnitude of electric current flowing through each coil, or selectively powering a particular combination of coils, e.g., the outer/inner coils or the top/bottom coils.

During processing, a gas, such as argon, is supplied to the processing region 210 from a gas source 242 via conduits 244. The gas source 242 may comprise an inert gas such as argon, krypton, helium or xenon, which is capable of energetically impinging upon and sputtering material from the sputtering target 232 and/or surface of the substrate 205 based on a bias applied by the bias source 241. The gas source 242 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 200 through exhaust ports 246 that receive spent process gas and direct the spent process gas to an exhaust conduit 248 having an adjustable position gate valve 247 to control the pressure in the processing region 210 in the processing chamber 200. The exhaust conduit 248 is connected to one or more exhaust pump 249, such as a cryopump. Typically, the pressure of the sputtering gas in the processing chamber 200 during processing is set to sub-atmospheric levels, such as a vacuum environment, for example, a pressure of about 0.6 mTorr to about 300 mTorr. In one embodiment, the processing pressure is set to about 20 mTorr to about 100 mTorr. A plasma is formed between the substrate 205 and the sputtering target 232 from the gas. Ions within the plasma are accelerated toward the sputtering target 232 and cause material to become dislodged from the sputtering target 232. The dislodged target material is deposited on the substrate.

The lid enclosure 291 generally comprises a conductive wall 285, a center feed 284 and shielding 286 (FIG. 2). In this configuration, the conductive wall 285, the center feed 284, the sputtering target 232 and a portion of the motor 293 enclose and form a back region 234. The back region 234 is a sealed region disposed on the backside of the sputtering target 232 and is generally filled with a flowing liquid during processing to remove the heat generated at the sputtering target 232 during processing. In one embodiment, the conductive wall 285 and center feed 284 are configured to support the motor 293 and magnetron system 289, so that the motor 293 can rotate the magnetron system 289 during processing. In one embodiment the motor 293 is electrically isolated from the RF or DC power delivered from the power supplies by use of a dielectric layer 294B, such as Delrin, G10, or Ardel.

The shielding 286 may comprise one or more dielectric materials that are positioned to enclose and prevent the RF energy delivered to the sputtering target 232 from interfering with and affecting other processing chambers disposed in the processing system 100 (FIG. 1). In one configuration, the shielding 286 may comprise a Delrin, G10, Ardel or other similar material and/or a thin-grounded sheet metal RF shield.

To provide efficient sputtering, a magnetron system 289 is positioned behind the sputtering target 232 in the upper process assembly 208 to create a magnetic field in the processing region 210 adjacent the sputtering surface 233 of the sputtering target 232, which creates a magnetron-controlled plasma 213. The magnetic field by magnetron system 289 is created to trap electrons and ions to increase the plasma density over one or more regions of the target 232, and to increase target utilization, control deposition uniformity and the sputtering rate. According to one embodiment of the disclosure, the magnetron system 289 includes a source magnetron assembly 221 that comprises an outer pole (not shown) and an inner pole (not shown). The magnetron system 289 is rotated about the central axis 294 of the processing chamber 200 by use of the motor 293. In some embodiments, a “closed loop” magnetron configuration is formed within the magnetron system 289 such that the outer pole (not shown) of the magnetron surrounds the inner pole (not shown) of the magnetron forming a gap between the poles that is a continuous loop. In the closed loop configuration, the magnetic fields that emerge and reenter through a surface of the sputtering target form a “closed loop” pattern can be used to confine electrons near the surface of the sputtering target in a closed pattern, which is often called a “racetrack” type pattern. A closed loop, as opposed to the open loop, magnetron configuration is able to confine electrons and generate a high density plasma near the sputtering surface 233 of the sputtering target 232 to increase the sputtering yield. In some other embodiments, an “open loop” magnetron configuration is formed within the magnetron system 289 such that the outer pole of the magnetron surrounds the inner pole of the magnetron forming a gap between the poles that is a continuous loop. In an open loop magnetron configuration, the electrons trapped between the inner and outer poles will migrate, leak out, and escape from the B-fields created at open ends of the magnetron, thus only holding the electrons for a short period of time during the sputtering process due to the reduced confinement of the electrons. It has been found that the use of an open loop magnetron configuration can provide significant step coverage improvements and provide an improved material composition uniformity across the substrate surface, when used in conjunction with the RF and DC sputtering of multi-compositional targets described herein.

In some embodiments of the processing chamber 200, the bias source 241 is coupled between an electrode and RF ground to adjust the bias voltage on the substrate 205 during processing to control the degree of bombardment on the substrate surface. In some embodiments, the electrode is disposed adjacent to the substrate receiving surface 227 of a support 226, and comprises the electrode 226A. In a PVD reactor, tuning of the bombardment of the substrate surface by the control of the impedance of the electrode to ground, will affect step coverage, overhang geometry and deposited film's properties, such as grain size, film stress, crystal orientation, film density, roughness, feature bottom coverage, feature step coverage and in some cases can effect film composition. Therefore, the bias source 241 can thus be used to alter the deposition rate, the etching rate, and even the composition of a multi-compositional film at the substrate surface. In one embodiment, the bias source 241 is employed to enable deposition or etching of a deposited film, by the appropriate adjustment of impedance of the electrode/substrate to ground. In one embodiment of the bias source 241, the bias source 241 that has a variable capacitor tuning circuit with a feedback circuit to control the properties of a deposited metal or non-metal layer on a substrate.

In some embodiments, the bias source 241 includes by an RF source (not shown) and an impedance match (not shown) that are coupled to the electrode 226A. In some embodiments, the RF power source is capable of generating RF currents at a frequency of between about 11 MHz and about 228 MHZ, such as 13.56 MHz at powers between about 0 and about 5 kWatts.

### Example Sputtering Process

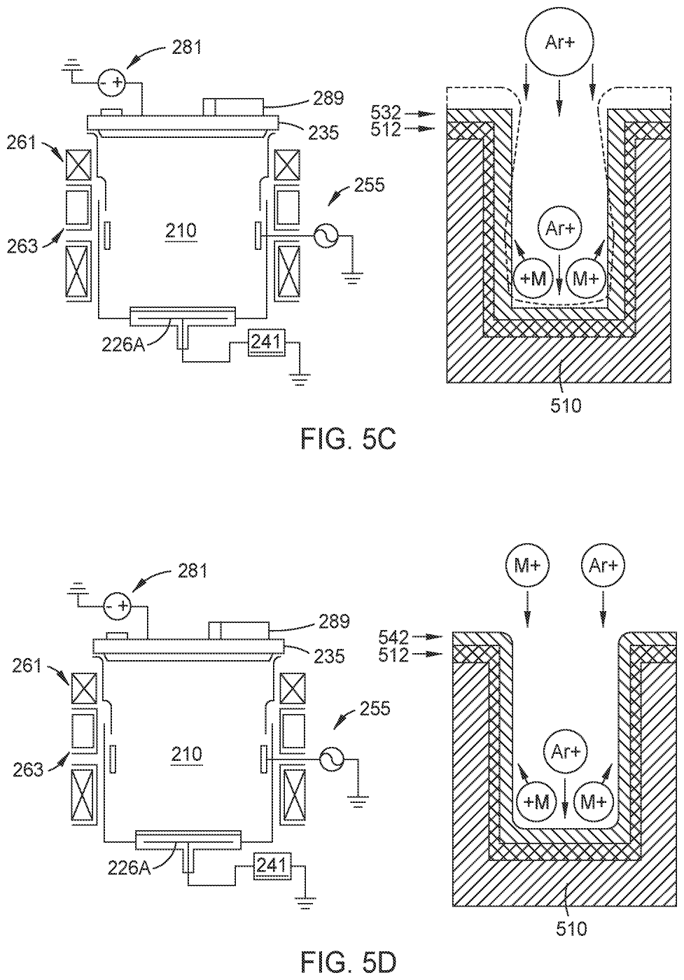

During a sputtering (deposition) process, the processing chamber is loaded with a substrate, and the chamber is pumped down to a predetermined base pressure of about 1×10−6 Torr to about 1×10−9 Torr. Then, a sputtering gas, such as argon, krypton, helium or xenon, is then introduced into the processing chamber via the gas source 242, and the sputtering gas pressure is controlled within a range of about 0.6 mTorr to about 300 mTorr, preferably between about 20 mTorr to about 100 mTorr. The gas flow rate can be controlled using a mass flow controller (not shown) to achieve the desired pressure range. One or more of the sources 281, 282 are configured to bias the target 232, while the source magnetron assembly 221 is in motion, and the RF coil 258 is biased to generate a plasma in the processing region 210 which contains both metal ions (e.g., M+ in FIGS. 5A-5B and 5D) and process gas ions. The pressure in the chamber can be increased over a standard deposition process, which results in a higher number of collisions in the plasma, and thus will reduce the ion energy near the surface of the substrate 205. In one example, the pressure in the processing region 210 during operation 310 is between about 1 mTorr and about 100 mTorr, versus a standard deposition process in which the pressure in the processing region 210 is between about 0.5 m Torr and about 50 mTorr. The plasma is formed by collisions between electrons generated in the plasma and the metal and/or gas ions or neutrals in the processing region of the process chamber. The plasma generates a significant number of low-energy ions, which are less damaging to the substrate and deposited layers.

During a sputtering process, the sputtering target 232 is biased with at least one of RF power and DC power by use of the RF source 281 and/or the DC source 282, respectively. The power supplied to the sputtering target 232 in one or more of the operations of method 300 is also referred to herein as a first target bias power. To create an efficient sputtering process, the magnetron system 289 positioned in the back of the sputtering target 232 in the upper process assembly 208 utilizes a generated magnetic field (e.g., a first magnetic field) that penetrates the processing region 210 adjacent to the sputtering surface 233 of the sputtering target 232, and allows the formation of the magnetron-controlled plasma 213. During Operation 310, a low power is supplied to the first RF source 281 and/or the DC source 282, to generate the magnetron-controlled plasma 213 that has a low plasma density, resulting in the generation lower energy metal ions and neutrals leaving the target surface 233 during the sputtering process and consequently creating a lower deposition rate deposition process. This creates a sputtering process that is slower, gentler ion bombardment-wise and less damaging to the material disposed on the surface of the substrate. During operation 310, RF power is also provided to the RF coil 258, which is configured to form a plasma (e.g., inductively coupled plasma 211) that has a relatively moderate to high plasma density, to improve the amount of ionization of the process gases and sputtered metal atoms, versus the plasma density of the metal ion plasma (e.g., magnetron-controlled plasma 213). The power supplied to the inductive coil 258 is also referred to as a first RF bias power. In this configuration, the reduced or lower plasma density in the metal ion plasma is created by lowering the applied voltage and/or power provided to the target 232 versus the amount of voltage and/or power provided to the target 232 in a standard deposition process. In one embodiment, the bias power applied to the target 232 is between about 5 KW and about 30 KW of DC power is provided by the DC source 282, and the RF power applied to the RF coil 258 is between about 0.5 and about 3 kW at a frequency of 13.56 MHz. In some embodiments, a collimator is disposed between the target and the inductive coil, and a pulsed voltage (PV) bias is applied to the collimator to modulate the ion directionality.

In some embodiments, during the sputtering process, the substrate 205 is biased with a negative DC voltage, pulsed-voltage, or RF power to attract positively charged ions, ionized by the plasma, towards it, which referred to herein as a substrate bias. The metal ions in the plasma are attracted towards the substrate 205 and deposit as a thin film. In other embodiments, during the sputtering process, the substrate 205 is biased with a pulsed-voltage (PV) waveform. The conditions used during the sputtering process, such as the amount of bias applied to the coil, the amount of bias applied to the target, the chamber pressure and the substrate bias level, are implemented to produce a deposited film that is formed at a reduced energy of the sputtered metal ions and neutrals, minimizing damage to the materials disposed at the surface of substrate 205.

### Example Pulsed Voltage Waveform

FIG. 4A illustrates an example graph 400 of different types of pulsed waveforms, waveform 425, and waveform 430, established at a substrate surface due (i.e., a substrate bias) to different voltage waveforms that are separately established at an electrode within the processing chamber by the bias source 241. The waveforms include two stages: an ion current stage during a first period of time and a sheath collapse stage during a second period of time, as shown. At the beginning of the ion current stage, a drop of substrate voltage creates a high voltage sheath above the substrate, accelerating positive ions to the substrate. The positive ions that bombard the surface of the substrate during the ion current stage deposit a positive charge on the substrate surface, which if uncompensated for causes a gradually increase the substrate voltage positively during the ion current stage, as illustrated by voltage waveform 425 in FIG. 4A. However, the uncontrolled accumulation of positive charge on the substrate surface undesirably gradually discharges the sheath and chuck capacitors, slowly decreasing the sheath voltage drop and bringing the substrate potential closer to zero, as illustrated by voltage waveform 425. The accumulation of positive charge results in the voltage drop in the voltage waveform established at the substrate surface (FIG. 4A). However, a pulsed voltage (PV) waveform that is established at the electrode (e.g., a substrate bias) that has a negative slope during the ion current stage can be generated so as to establish a square shaped region (e.g., near zero slope) for an established substrate voltage waveform, as shown by curve 430 in FIG. 4A. The first voltage of the PV waveform may be between about negative 100 volts (V) to about negative 2000 V. For example, the first voltage of the PV waveform may be about negative 200 V. For example, the first voltage of the PV waveform may be about negative 600 V. For example, the first voltage of the PV waveform may be about negative 1500 V. Implementing the slope in the waveform established at the electrode during the ion current stage may be referred to as current compensation. The voltage difference between the beginning and end of the ion current phase determines an ion energy distribution function (IEDF) width. The greater the voltage difference, the wider the IEDF width. To achieve mono-energetic ions and a narrower IEDF width, operations are performed to flatten the substrate voltage waveform in the ion current phase using current compensation.

FIG. 4B is a graph 450 illustrating an ion energy distribution function (IEDF), in accordance with certain embodiments of the present disclosure. Graph 450 includes a vertical axis plotting the ion population of an IEDF, and a horizontal axis plotting ion energy. Graph 450 depicts an IEDF plot for three different waveforms, a 400 KHz pulsed-voltage (PV) waveform 402, a 13 MHz RF waveform 404, and a 2 MHz RF waveform 406.

As shown, the 400 KHz PV waveform 402 exhibits a high magnitude narrow single-peak IEDF. The IEDF of the 400 KHz PV waveform 402 also occurs over a narrow band of ion energies. This is due to the pulsed nature of the 400 KHz PV waveform 402. In comparison to the 400 KHz PV waveform 402, the 13 MHz RF waveform 404 exhibits a two-peak (bi-energetic) IEDF. The magnitude of the peaks of the two-peak IEDF for the 13 MHz RF waveform 404 are approximately half of the magnitude of the single-peak IEDF of the 400 KHz PV waveform 402. Additionally, the two-peak IEDF for the 13 MHz RF waveform 404 occurs over a wider range of ion energies when compared to the 400 KHz PV waveform 402. The two-peak IEDF across a wider range of ion energies is due to the sinusoidal nature of the RF waveform. The 2 MHz RF waveform 406 also exhibits a two-peak (bi-energetic) IEDF. In this instance, the magnitude of the peaks of the two-peak IEDF for the 2 MHz RF waveform 406 are approximately one-fifth the magnitude of the single-peak IEDF of the 400 KHz PV waveform 402. In addition to the lower magnitude, the two-peak IEDF for the 2 MHz RF waveform 406 occurs over a much larger range of ion energies when compared to the 13 MHz RF waveform 404 and the 400 kHz PV waveform 402.

The narrow band of ion energies at the high magnitude single-peak exhibited by the 400 KHz PV waveform 402 is preferable over the wider ion energy band and two-peak IEDF exhibited by the 13 MHz RF waveform 404 and the 2 MHz RF waveform 406. The single-peak of the 400 KHz PV waveform 402 offers higher peak power, better control over the power delivered, and improved control over the bombardment angle (e.g., better verticality) when compared to the 13 MHz RF waveform 404 and the 2 MHz RF waveform 406. Some embodiments are directed to techniques for implementing the ion energy distribution shown in FIG. 4B using a PV waveform tailoring technique, as described in more detail herein.

### Example Process Sequence

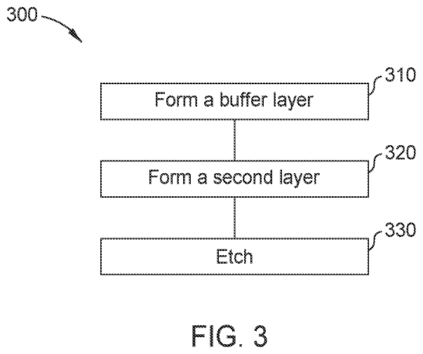

FIG. 3 illustrates a process flow diagram of a method 300 according to one or more embodiments described herein. Method 300 includes a plurality of operations. Operation 310 includes forming a buffer layer. Operation 320 includes forming a second layer over the buffer layer. Operation 330 includes resputtering at least a portion the first layer and second layer. Method 300 may be understood with reference to FIGS. 4A-4B, and 5A-5D. In some embodiments, the operations of method 300 can be performed using the processing chamber 200 shown in FIG. 2. While the operations of method 300 are described using processing chamber 200, other processing chamber types and plasma generation techniques are considered within the scope of this disclosure. In other embodiments, the operations of method 300 may be performed in a series of processing chambers. For example, operation 310 and operation 320 may be performed in a first process chamber and operation 330 may be performed in a second process chamber, or any combination of process chambers and the operations of method 300.

In method 300, operation 310 is used to create a thin-deposited layer 512 on the substrate surface to isolate the surface of the substrate and mitigate damage to the substrate during subsequent processing activities. The thin-deposited layer 512 is often referred to herein as the “physical buffer layer”, or simply the “buffer layer,” which in some embodiments can be different from a diffusion barrier layer, liner layer or wetting layer. Operation 310 is then followed by the operation 320 to ensure a desired step coverage and operation 330 employs etching process to remove, or adjust the profile of, any material overhang formed within the features formed on the substrate.

At operation 310 of method 300, as seen in FIG. 5A, a buffer layer 512 is formed. The buffer layer 512 may be formed by use of a sputtering process described above. The buffer layer 512 (e.g., first deposited layer) is formed on the field, sidewall, and bottom of a dielectric device feature 510 (FIG. 5A). The buffer layer is generally a thin film coating that has a desirable step, sidewall and bottom coverage as shown in FIG. 5A as a deposited film that includes a field portion 514, a sidewall portion 516, and a bottom portion 518. The combined all three portions of the thin film coating act as a protective buffer layer, such that the subsequent deposition step with higher ion energy will not damage the underlying layers, such as a previously deposited diffusion barrier layer, liner layer, wetting layer or dielectric materials within the device features. In some embodiments, the low energy deposition process results in minimized damage to the substrate 205 and/or prior deposited layers, making operation 310 ideal for delicate materials, such as low-K dielectrics. In some embodiments, operation 310 is designed to be a low-damage process, which forms a thin buffer layer to protect the underlying dielectric material from any damage caused by the application of subsequent high-energy and/or high deposition rate material deposition step performed in the same process chamber. Operation 310 can be used to deposit a variety of materials, including molybdenum (Mo), copper (Cu), tungsten (W), titanium (Ti), aluminum (Al), tantalum (Ta), and nickel (Ni), onto a substrate 205 with minimal damage. In some embodiments, the resulting thin film buffer layer 512 (e.g., a first deposited layer) deposited during operation 310 has a thickness between about 10 angstroms (Å) and about 100 Å across different portions.

Once operation 310 is complete, operation 320 of method 300 begins. Operation 320 of method 300 includes forming a second layer 522, such as, for example, sputtering a copper (Cu), aluminum (Al), molybdenum (Mo), ruthenium (Ru), cobalt (Co), or tungsten (W) film, or combination thereof. In some embodiments, the operation 320 is performed in the same process chamber as operation 310. The second layer 522 created by the operation 320 can include a bottleneck, or narrowed, structure that is created by the overhang of deposited material, as shown in FIG. 5B. The overhang 524, which is due to the rapid accumulation of deposited metal near the entrance of the device features. The overhang 524 narrows the entrance, blocks metal entering into the feature, and shadows the deposition on the sidewalls, therefore, resulting in poor sidewall coverage 526 of the device features. The overall thickness of the second layer 522 is between about 100 angstroms (Å) and about 1000 Å. The parameters for operation 320 can be controlled to optimize the thickness, uniformity, step-coverage, bottom-coverage, and morphology of the film. For example, the applied DC power, PV waveform characteristics, the substrate bias, deposition time, and gas pressure can be adjusted to control the ion flux and ion energy, which affect the film's profile, morphology, and properties. In one example, the applied DC power, and the substrate bias (e.g., PV waveform), deposition time, and gas pressure can be adjusted to control the ion flux, IEDF and ion energy, which affect the film's profile, morphology, and properties. The substrate 205 temperature can also be controlled to optimize the adhesion and crystallographic orientation of the film.

Once operation 320 is complete, operation 330 is performed. Operation 330 of method 300 includes resputtering the films (e.g., Cu, Mo, Ru, Co, or W films) formed on the surface of the substrate 205, or sometimes referred to herein as an etching process. As shown in FIG. 5C, operation 330 removes, and/or redistributes the material found in the overhang 524 that may have formed on the substrate 205 during the operation 320. It has been found that operation 330 also improves sidewall coverage 526 through the resputtering process. During operation 330, an inert gas such as argon, krypton, helium, or xenon, is introduced into the processing chamber 200 through the gas source 242 and the conduits 244. The inert gas then flows into the processing region 210 and interacts with a plasma 211 formed therein during operation 320 and/or generated or sustained by a bias applied by the bias source 241. The plasma then interacts with the process gas, creating energetic ion species (e.g., gas ions and sputtered atom ions) that are directed towards the substrate 205 by a PV waveform applied to the substrate 205 by the bias source 241. As shown above in FIG. 4A, the voltage of the PV waveform (the substrate bias) applied to the substrate 205 by the bias source 241 may include voltage waveform pulse that has an “on” period (e.g., ion current phase) where a bias of between about negative 100 volts (V) to about negative 2000 V is applied. In some embodiments, a single-peak IEDF is generated for the ions formed within the plasma formed within the processing volume by providing a 100-500 KHz PV waveform, or a 350 kHz to 450 kHz PV waveform, such as a 400 KHz PV waveform during the sputtering process performed during operation 320 to create a higher ion energy peak power, better ion energy control over the power delivered, and improved control over the ion bombardment angle (e.g., better verticality) during operation 320.

In some embodiments of operation 320, the plasma is generated or maintained by the inductive coil assembly 255 to enhance the resputtering process by increasing the ionization of the gas atoms and the resulting ion species. By altering the radial distribution of the plasma, the electromagnet assemblies can also be used to help improve the etching or material redistribution process across the surface of the substrate 205, and provide more precise control over the etching or material redistribution process.

During operation 330, the ionized argon atoms physically bombard the surface and ballistically knock out and/or sculpt the shape of the film. The overhang portion of the deposited film can be etched away faster and in a more controlled manner than other regions in the device features due to the directionality of the ions (e.g., inert gas ions) in the plasma that are controlled by the use of the substrate bias. As shown in FIG. 5C, a resputtering process, which removes and redistributes deposited metals within the device feature, in particular the bottom region, results in a modified metal film layer 532, which has improved sidewall and bottom coverage. As noted above, during the resputtering process, the generated plasma can be used to redistribute metal atoms positioned at the bottom portion of the feature and redeposit metal atoms on the sidewall portions, resulting in a subtraction of materials on the overhang and at the bottom portion and addition of materials at the sidewall portions. This redistribution of material improves the sidewall coverage and film thickness uniformity. The parameters of operation, such as gas composition, gas flow rate, pressure, and substrate bias characteristics, can be optimized to achieve the desired etching rate, selectivity, and profile. For example, by adjusting the applied voltage of the PV waveform (e.g., the substrate bias), the depth and energy of the ion bombardment, and thus resputtering processes, allow for fine tuning of material removal, redeposition, and feature profile control. Similar to the discussion above, in some embodiments of operation 330, a single-peak IEDF is generated for the ions formed within the plasma formed within the processing volume by providing a 100-500 KHz PV waveform, or a 350 kHz to 450 KHz PV waveform, such as a 400 KHz PV waveform during operation 330 to create a higher ion energy peak power, better ion energy control over the power delivered, and improved control over the ion bombardment angle (e.g., better verticality) during operation 330.

In some embodiments, operation 320 and operation 330 are performed simultaneously, herein after referred to as Simultaneous Deposition and Etching (SIE). Prior to SIE, operation 310 is performed to create a thin and more conformal buffer layer on the substrate surface as described above. During SIE, simultaneous deposition and etching are performed (FIG. 5C). This processing mode combines operation 320 and operation 330. This is made possible by leveraging both the magneton-controlled plasma 213 and biasing of the substrate using a PV waveform in a synchronized process step.

The combination of the sputtering and etching process created by implementation of the PV waveform substrate bias allows for simultaneous deposition and etching of the substrate 205, increasing the deposition rate, improving step coverage process results, and increasing throughput. Combining operation 320 and operation 330 offers several advantages over traditional PVD and etching processes. First, SIE eliminates the need for separate PVD and etching steps, reducing the time and resources required for these processes, leading to increased process efficiency and throughput. In addition, the simultaneous deposition and etching operations ensure that the deposited and redeposited material reaches all desired areas of the features formed in the substrate 205, resulting in improved step coverage. Moreover, the simultaneous deposition and etching operations can reduce the overhang that is typically formed during the PVD process. Overall, combining operation 320 and operation 330 provides a low damage deposition process for metal layers with high aspect ratios and good step coverage while minimizing damage to underlying layers and reducing contamination. This is particularly advantageous for applications that require a low-damage process, such as for low K dielectric materials.

In other embodiments, operation 310, operation 320, and operation 330, of method 300 are performed as a sequential process, making it easier to control than some other process sequences. Each operation sequentially building on the previous operation, ensuring that the desired outcome is achieved at each operation.

In some embodiments of the method 300, the sputtering process used to form the buffer layer 512 during operation 310 may also utilize a sputtering process that is similar to the processes described in operations 320 and 330. In one example, the buffer layer target is biased by use of a DC power and the substrate is biased using PV waveform to form a substantially conformal buffer layer. Moreover, during operation 310 the DC power, PV waveform, deposition time, and gas pressure can be adjusted to control the ion flux, IEDF and ion energy, which affect the buffer layer film's profile, morphology, and properties.

### Additional Considerations

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, “controller”, “a processor”, “at least one processor”, or “one or more processors”, generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “a memory”, “at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112 (f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. A method for fabricating a semiconductor device, comprising:
forming, within a physical vapor deposition (PVD) chamber, a first layer by use of a PVD process on a surface of substrate that comprises a plurality of features formed therein, wherein forming the first layer comprises biasing a target within the process chamber; and
etching, within the PVD chamber, at least a portion of the first layer, wherein the etching comprises:
applying a substrate bias to an electrode disposed within a substrate support near a substrate receiving surface, wherein applying the substrate bias comprises delivering a pulsed-voltage (PV) waveform to the electrode; and
exposing the substrate to a plasma generated within the PVD chamber.

2. The method of claim 1, wherein delivering the PV waveform comprises:
delivering a first voltage to the electrode disposed within the substrate support for a first period of time; and
halting delivery of the first voltage to the electrode disposed within the substrate support for a second period of time.

3. The method of claim 2, wherein the first voltage is about negative 100 V to about negative 2000 V.

4. The method of claim 1, further comprising adjusting a first voltage of the PV waveform to adjust a depth of etching of at least the portion of the first layer, wherein the first voltage is about negative 100 V to about negative 2000 V.

5. The method of claim 1, wherein forming the first layer, and etching at least a portion of the first layer, occur simultaneously.

6. The method of claim 5, wherein the simultaneous forming and etching of the first layer cause a simultaneous deposition and redeposition of one or more materials of the first layer to improve step coverage.

7. The method of claim 1, further comprising altering a radial distribution of the plasma generated within the process chamber, wherein altering the radial distribution of the plasma further comprises delivering an electric current to one or more electromagnet assemblies aligned around the process chamber.

8. A method for fabricating a semiconductor device, comprising:
forming, within a first physical vapor deposition (PVD) chamber, a first layer on a surface of substrate that comprises a plurality of features formed therein, wherein forming the first layer comprises biasing a target within the first PVD chamber;
transferring the substrate from the first PVD chamber to a second PVD chamber; and
etching, within the second PVD chamber, at least a portion of the first layer, wherein the etching comprises:
applying a substrate bias to an electrode disposed within a substrate support near a substrate receiving surface, wherein applying the substrate bias comprises delivering a PV waveform to the electrode; and
exposing the substrate to a plasma generated within the second PVD chamber.

9. The method of claim 8, wherein delivering the PV waveform comprises:
delivering a first voltage to the electrode disposed within the substrate support for a first period of time; and
halting delivery of the first voltage to the electrode disposed within the substrate support for a second period of time.

10. The method of claim 9 wherein the first voltage is about negative 100 V to about negative 2000 V.

11. The method of claim 8, further comprising adjusting a first voltage of the PV waveform to adjust a depth of etching of at least the portion of the first layer, wherein the first voltage is about negative 100 V to about negative 2000 V.

12. The method of claim 8, further comprising biasing a target within the second process chamber, and etching at least a portion of the first layer, occur simultaneously.

13. The method of claim 12, wherein the simultaneous biasing the target, and etching of the first layer, within the second process chamber, cause a simultaneous deposition and redeposition of one or more materials of the first layer to improve step coverage.

14. The method of claim 8, further comprising altering a radial distribution of the plasma generated within the second process chamber, wherein altering the radial distribution of the plasma further comprises delivering an electric current to one or more electromagnet assemblies aligned around the second process chamber.
